(19) United States
(12) Patent Application Publication
(10) Pub. No.: US 2024/0387641 A1
(43) Pub. Date: Nov. 21, 2024

(54) NITRIDE SEMICONDUCTOR DEVICE AND METHOD OF MANUFACTURING THE SAME

(71) Applicant: FUJI ELECTRIC CO., LTD., Kawasaki-shi (JP)

(72) Inventors: Yuki OHUCHI, Tokyo (JP); Katsunori UENO, Matsumoto-city (JP); Ryo TANAKA, Tokyo (JP); Shinya TAKASHIMA, Tokyo (JP)

(73) Assignee: FUJI ELECTRIC CO., LTD., Kawasaki-shi (JP)

(21) Appl. No.: 18/606,227

(22) Filed: Mar. 15, 2024

(30) Foreign Application Priority Data
May 15, 2023 (JP) 2023-080128

(51) Int. Cl. H01L 29/20; H01L 29/66; H01L 29/78

(52) U.S. Cl. CPC H01L 29/2003; H01L 29/66712; H01L 29/7804

(57) ABSTRACT

Provided is a nitride semiconductor device including a p-type region having a high concentration, and a method of manufacturing the same. The nitride semiconductor device includes a nitride crystal layer, and a p-type region provided in the nitride crystal layer. The p-type region includes Mg at a concentration in a range of 3×10¹⁸ cm⁻³ or greater and 1×10²¹ cm⁻³ or less, and at least either a group-13 element or an acceptor element at a concentration in a range of 3×10¹⁷ cm⁻³ or greater and 5×10²¹ cm⁻³ or less.

### CROSS-REFERENCE TO RELATED APPLICATION

This application claims benefit of priority under 35 USC 119 based on Japanese Patent Application No. 2023-080128 filed on May 15, 2023, the entire contents of which are incorporated by reference herein.

### BACKGROUND OF THE INVENTION

### 1. Field of the Invention

The present invention relates to nitride semiconductor devices and methods of manufacturing the same.

### 2. Description of the Related Art

Nitride semiconductor devices are known that have a vertical metal oxide semiconductor (MOS) structure, as disclosed in JP 2019-096744 A, for example. Such a nitride semiconductor device uses magnesium (Mg) as a dopant so as to control a conductivity of p-type, as disclose in JP 2014-086698 A, for example.

This type of nitride semiconductor device needs to be selectively provided with a p-type region having a high impurity concentration in order to achieve a good ohmic contact. However, it is difficult to form the p-type region with the high concentration by ion implantation, since the p-type region tends to cause segregation of Mg, leading to a decrease in concentration accordingly.

### SUMMARY OF THE INVENTION

In view of the foregoing problems, the present invention provides a nitride semiconductor device including a p-type region having a high concentration, and a method of manufacturing the same.

To solve the problems described above, a nitride semiconductor device according to an aspect of the present disclosure includes a nitride crystal layer, and a p-type region provided in the nitride crystal layer, wherein the p-type region includes Mg at a concentration in a range of 3×10¹⁸ cm⁻³ or greater and 1×10²¹ cm⁻³ or less, and at least either a group-13 element or an acceptor element at a concentration in a range of 3×10¹⁷ cm⁻³ or greater and 5×10²¹ cm⁻³ or less.

A method of manufacturing a nitride semiconductor device according to another aspect of the present disclosure includes introducing Mg to a nitride crystal layer at a concentration in a range of 3×10¹⁸ cm⁻³ or greater and 1×10²¹ cm⁻³ or less, introducing at least either a group-13 element or an acceptor element to a region of the nitride crystal layer to which Mg is introduced at a concentration in a range of 3×10¹⁷ cm⁻³ or greater and 5×10²¹ cm⁻³ or less, and forming a p-type region in the nitride crystal layer by subjecting, to annealing, the nitride crystal layer to which Mg and at least either the group-13 element or the acceptor element are introduced so as to activate Mg.

### BRIEF DESCRIPTION OF THE DRAWINGS

FIG. 1 is a plan view illustrating a configuration example of a GaN semiconductor device according to Embodiment 1 of the present disclosure;

FIG. 2 is a cross-sectional view illustrating the configuration example of the GaN semiconductor device according to Embodiment 1 of the present disclosure;

FIG. 3 is an enlarged cross-sectional view of FIG. 2, illustrating one vertical MOSFET;

FIG. 4 is a model diagram illustrating a bonded state of atoms of GaN crystals doped with Mg;

FIG. 5 is a graph showing calculation results of internal pressures of GaN crystals obtained by a first-principles calculation in which each of B, Al, Li, and B is substituted for a Ga site of the GaN crystals;

FIG. 6 is a graph showing calculation results of internal pressures of GaN crystals obtained by the first-principles calculation in which at least either Al or Be and Mg are substituted for the Ga site of the GaN crystals;

FIG. 7 is a cross-sectional view illustrating a sequential procedure of Manufacturing Method Example 1 of a method of manufacturing the GaN semiconductor device according to Embodiment 1 of the present disclosure;

FIG. 8 is a cross-sectional view illustrating the sequential procedure of Manufacturing Method Example 1 of the method of manufacturing the GaN semiconductor device according to Embodiment 1 of the present disclosure;

FIG. 9 is a cross-sectional view illustrating a sequential procedure of Manufacturing Method Example 2 of the method of manufacturing the GaN semiconductor device according to Embodiment 1 of the present disclosure;

FIG. 10 is a cross-sectional view illustrating the sequential procedure of Manufacturing Method Example 2 of the method of manufacturing the GaN semiconductor device according to Embodiment 1 of the present disclosure;

FIG. 11 is a cross-sectional view illustrating a sequential procedure of Manufacturing Method Example 3 of the method of manufacturing the GaN semiconductor device according to Embodiment 1 of the present disclosure;

FIG. 12 is a cross-sectional view illustrating the sequential procedure of Manufacturing Method Example 3 of the method of manufacturing the GaN semiconductor device according to Embodiment 1 of the present disclosure;

FIG. 13 is a cross-sectional view illustrating a sequential procedure of Manufacturing Method Example 4 of the method of manufacturing the GaN semiconductor device according to Embodiment 1 of the present disclosure;

FIG. 14 is a cross-sectional view illustrating the sequential procedure of Manufacturing Method Example 4 of the method of manufacturing the GaN semiconductor device according to Embodiment 1 of the present disclosure;

FIG. 15 is a cross-sectional view illustrating a configuration of a vertical MOSFET according to a modified example of Embodiment 1 of the present disclosure;

FIG. 16 is a cross-sectional view illustrating a configuration example of a vertical MOSFET according to Embodiment 2 of the present disclosure;

FIG. 17 is a cross-sectional view illustrating a configuration of a vertical MOSFET of Modified Example 1 of Embodiment 2 of the present disclosure;

FIG. 18 is a cross-sectional view illustrating a configuration of a vertical MOSFET of Modified Example 2 of Embodiment 2 of the present disclosure; and

FIG. 19 is a cross-sectional view illustrating a configuration example of a p-n diode according to Embodiment 3 of the present disclosure.

### DETAILED DESCRIPTION

Some embodiments according to the present disclosure are descried below.

In the following explanations regarding the drawings, the same or similar components are denoted by the same or similar reference numerals. The drawings are illustrated schematically, and relationships between thicknesses and planar dimensions, and proportions of the thicknesses of the respective members are not drawn to scale. The specific thicknesses and dimensions therefore should be determined in accordance with the explanations below. It should also be understood that the relationships or proportions of the dimensions between the drawings can differ from each other.

The following explanations may refer to the respective directions as an X-axis direction, a Y-axis direction, and a Z-axis direction. For example, the X-axis direction and the Y-axis direction are each a direction parallel to a front surface 10a of a GaN substrate 10 described below. The Z-axis direction is a direction orthogonal to the front surface 10a of the GaN substrate 10. The X-axis direction, the Y-axis direction, and the Z-axis are perpendicular to each other.

In the following explanations, the positive direction in the Z-axis may be referred to as an “upper side”, and the negative direction in the Z-axis may be referred to as a “lower side”. The definitions of the “upper side” and the “lower side” do not necessarily mean the directions vertical to the ground. In other words, the respective directions of the “upper side” and the “lower side” are not limited to the gravity direction. The definitions regarding the “upper side” and the “lower side” are used only for illustration purposes to define the relative positional relationship among regions, layers, films, and a substrate, which do not limit the technical idea of the present invention. For example, when the observing direction of the sheet is changed by 180 degrees, the definitions of the “upper side” and the “lower side” shall be reversed.

The following embodiments are illustrated with a case in which a first conductivity-type is a p-type, and a second conductivity-type is an n-type. The respective embodiments, however, may employ the opposite conductivity relation so as to define the first conductivity-type as an n-type and the second conductivity-type as a p-type. The signs “+” and “−” added to the signs “p” and “n” used for semiconductor regions signify that the respective semiconductor regions have either a higher impurity concentration or a lower impurity concentration than other semiconductor regions without the sign “+” or “−” added. It should be understood that the respective semiconductor regions to which the same sign “p” (or the same sign “n”) is added do not necessarily or strictly have the same impurity concentration.

### Embodiment 1

### Configuration Example

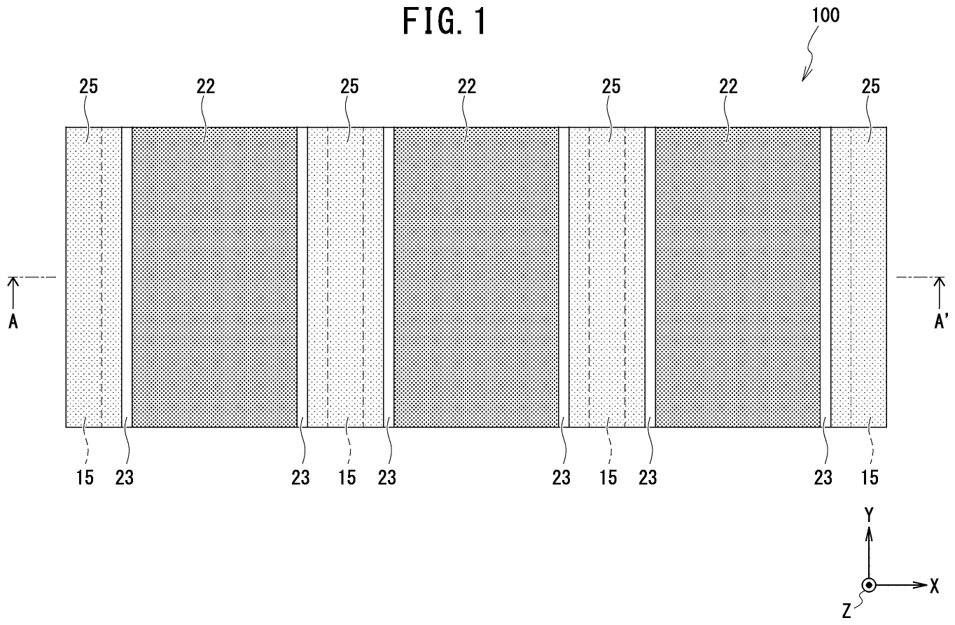

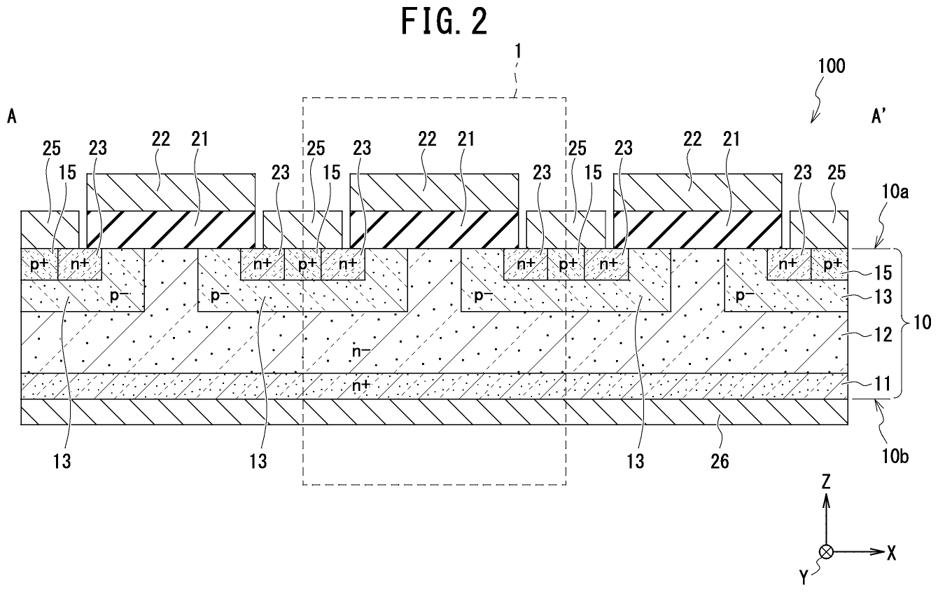

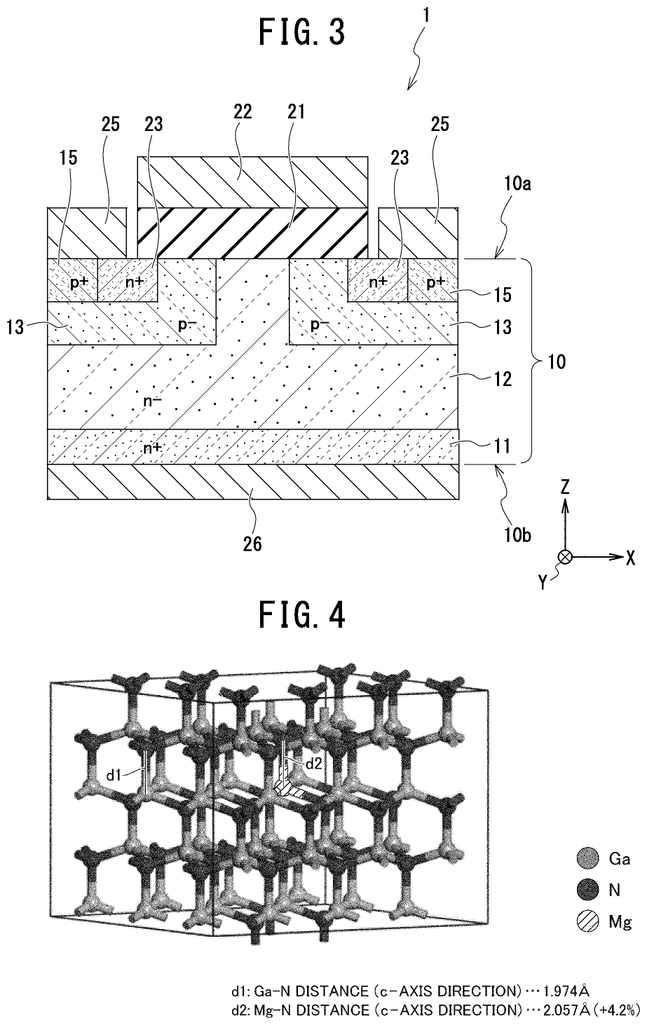

FIG. 1 is a plan view illustrating a configuration example of a gallium nitride (GaN) semiconductor device 100 according to Embodiment 1 of the present disclosure, which is an example of a nitride semiconductor device according to the present disclosure. FIG. 2 is a cross-sectional view illustrating the configuration example of the GaN semiconductor device 100 according to Embodiment 1 of the present disclosure. FIG. 2 illustrates the cross section taken along line A-A′ in the plan view of FIG. 1. FIG. 3 is a partly enlarged cross-sectional view of FIG. 2, illustrating one vertical MOSFET 1.

The GaN semiconductor device 100 illustrated in FIG. 1 and FIG. 2 is a power device. As illustrated in FIG. 1 and FIG. 2, the GaN semiconductor device 100 includes a GaN substrate 10 having a front surface 10a and a rear surface 10b, and a plurality of vertical metal-oxide-semiconductor field-effect-transistors (MOSFETs) 1 provided in the GaN substrate 10. The vertical MOSFETs 1 are each an example of a field-effect-transistor according to the present disclosure. The plural vertical MOSFETs 1 are arranged repeatedly in one direction, which is the X-axis direction, for example. Each of the vertical MOSFETs 1 is a single unit of repeatedly-arranged structures, and the plural single units are aligned in one direction.

As illustrated in FIG. 1 to FIG. 3, the GaN substrate 10 includes a GaN single-crystal substrate 11 of n⁺-type, which is an example of a nitride crystal substrate according to the present disclosure, and a GaN layer 12 of n⁻-type, which is an example of a nitride crystal layer according to the present disclosure, provided on the GaN single-crystal substrate 11. The GaN single-crystal substrate 11 is a c-plane n⁺-type GaN single-crystal substrate, for example. The n-type impurities in the GaN single-crystal substrate 11 include one or more of silicon (Si), oxygen (O), and germanium (Ge). For example, the GaN single-crystal substrate 11 includes Si as the n-type impurities at an impurity concentration of 5×10¹⁷ cm⁻³ or greater.

The GaN single-crystal substrate 11 may be a low-dislocation free-standing substrate having a dislocation density of less than 1×10⁷ cm⁻². The provision of the GaN single-crystal substrate 11 of such a low-dislocation free-standing substrate also leads a dislocation density of the GaN layer 12 provided on the GaN single-crystal substrate 11 to be decreased. The use of the low-dislocation free-standing substrate can also decrease a leakage current in the power device regardless of whether the power device having a large area is provided in the GaN substrate 10. A manufacturing apparatus thus can manufacture such power devices at a high non-defect rate. Further, the implanted impurity ions can be prevented from being diffused deeply in association with the dislocation during annealing.

The GaN layer 12 is a single-crystal GaN layer epitaxially grown on one of the surfaces of the GaN single-crystal substrate 11. The GaN layer 12 is obtained such that n-type impurities are doped during the epitaxially-growing process. The n-type impurities are Si, for example. The GaN layer 12 includes the impurities of Si at a concentration in a range of 1×10¹⁵ cm⁻³ or greater and 5×10¹⁶ cm⁻³ or less, for example.

The vertical MOSFET 1 includes a well region 13 of p⁻-type and a contact region 15 of p⁺-type each provided on the front surface 10a side of the GaN substrate 10 toward the front surface of the n⁻-type GaN layer 12. The vertical MOSFET 1 further includes a gate insulating film 21 deposited on the front surface 10a of the GaN substrate 10, a gate electrode 22 further deposited on the gate insulating film 21, a source electrode 25 provided on the front surface 10a of the GaN substrate 10 so as to be in contact with a source region 23 and the contact region 15, and a drain electrode 26 provided toward the rear surface 10b of the GaN substrate 10 so as to be in contact with the n⁺-type GaN single-crystal substrate 11. The p⁻-type well region 13, the n⁺-type source region 23, and the p⁺-type contact region 15, which is an example of a “p-type region” according to the present disclosure, are provided toward the front surface 10a of the GaN substrate 10 (toward the front surface of the n⁻-type GaN layer 12). The p-type well region 13 is also referred to below as a p-type GaN layer.

The well region 13 is a p-type layer obtained such that p-type impurity ions such as Mg implanted to the front surface 10a side of the GaN substrate 10 are activated by annealing. The concentration of the p-type impurities of Mg contained in the well region 13 is in a range of 1×10¹⁷ cm⁻³ or greater and 3×10¹⁸ cm⁻³ or less, for example. The well region 13 is deposited to have a surface at the same level as the front surface 10a of the GaN substrate 10. The surface of the well region 13 is in contact with the gate insulating film 21. A channel of the vertical MOSFET 1 is provided on and around the surface of the well region 13 in contact with the gate insulating film 21.

The source region 23 is an n⁺-type layer obtained such that n-type impurity ions such as Si and O implanted to the front surface 10a side of the GaN substrate 10 are activated by annealing. The concentration of the n-type impurities of Si contained in the source region 23 is in a range of 1×10¹⁹ cm⁻³ or greater and 5×10²⁰ cm⁻³ or less, for example. The source region 23 is provided in the well region 13 located under the respective lateral sides of the gate electrode 22 so as to have a surface at the same level as the front surface 10a of the GaN substrate 10. The source region 23 is located inside the well region 13 so as to be in contact with the well region 13.

The contact region 15 is a p⁺-type layer obtained such that p-type impurity ions such as Mg implanted to the front surface 10a side of the GaN substrate 10 are activated by annealing. The concentration of the p-type impurities of Mg contained in the contact region 15 is in a range of 3×10¹⁸ cm⁻³ or greater and 1×10²¹ cm⁻³ or less, and more preferably in a range of 1×10¹⁹ cm⁻³ or greater and 2×10²⁰ cm⁻³ or less.

The contact region 15 further includes at least either a group-13 element or an acceptor element at a concentration in a range of 3×10¹⁷ cm⁻³ or greater and 5×10²¹ cm⁻³ or less, and more preferably in a range of 5×10¹⁸ cm⁻³ or greater and 4×10²⁰ cm⁻³ or less, in order to reduce a compressive stress field caused around Mg. The group-13 element is at least either B or Al, for example. The acceptor element is at least either Li or Be, for example. The contact region 15 contains Al as the group-13 element, for example, at a concentration in a range of 3×10¹⁷ cm⁻³ or greater and 5×10²¹ cm⁻³ or less, and more preferably in a range of 5×10¹⁸ cm⁻³ or greater and 4×10²⁰ cm⁻³ or less.

As described above, the GaN layer 12 is the single-crystal GaN layer epitaxially grown on one of the surfaces of the GaN single-crystal substrate 11. The well region 13 and the contact region 15 are each provided in the single-crystal GaN layer. This configuration leads a lattice constant of the contact region 15 in each of the X-axis direction that is as an example of a “first direction” according to the present disclosure and the Y-axis direction that is as an example of a “second direction” according to the present disclosure to be equal to a lattice constant of the GaN single-crystal substrate 11 in each of the X-axis direction and the Y-axis direction.

The contact region 15 is deposited to have a surface at the same level as the front surface 10a of the GaN substrate 10. The contact region 15 is provided inside the well region 13 so as to be in contact with the well region 13. The contact region 15 is also in contact with the source region 23. The well region 13 is connected to the source electrode 25 through the contact region 15. This configuration leads a potential of the well region 13 to be kept at a potential of the source electrode 25, which is a reference potential such as a ground potential (GND), for example.

The gate insulating film 21 is a SiO₂ film, for example. The gate insulating film 21 may be a single-layer film of at least one of an Al₂O₃ film, a SiON film, an AlSiO film, and an AlON film, or may be a stacked-layer film including some of a SiO₂ film, an Al₂O₃ film, a SiON film, an AlSiO film, and an AlON film. A thickness of the gate insulating film 21 is in a range of 50 nanometers or greater and 150 nanometers or smaller, and is 100 nanometers, for example.

The gate electrode 22 is located adjacent to a region provided with a channel (referred to below as a “channel region”) with the gate insulating film 21 interposed. The gate electrode 22 includes polysilicon doped with metal or impurities such as Al, Ti, Ni, or W. The gate electrode 22 may include silicide such as WSi or NiSi instead. The source electrode 25 is in ohmic contact with each of the source region 23 that is the n⁺-type layer and the contact region 15 that is the p⁺-type layer. The drain electrode 26 is in ohmic contact with the surface of the n⁺-type GaN single-crystal substrate 11 on the opposite side of the surface in contact with the GaN layer 12.

The source electrode 25 and the drain electrode 26 each include Al, an Al—Si alloy, Ni, a Ni alloy, a Ti—Al alloy, or a Ni—Au alloy, for example. The source electrode 25 may be provided with a barrier metal layer between the source electrode 25 and the source region 23. The drain electrode 26 may be provided with a barrier metal layer between the drain electrode 26 and the n⁺-type GaN single-crystal substrate 11. The respective barrier metal layers may include titanium (Ti).

More particularly, the source electrode 25 and the drain electrode 26 may each be a stacked layer including a Ti layer and an Al layer or a stacked layer including a Ti layer and an Al—Si alloy layer. The source electrode 25 may be an electrode serving also as a source pad not illustrated or provided independently of the source pad. The drain electrode 26 may be an electrode serving also as a drain pad illustrated or provided independently of the drain pad.

### (Formation of Compressive Stress Field)

FIG. 4 is a model diagram illustrating a bonded state of atoms of GaN crystals doped with Mg. The inventors of the present disclosure executed a structure optimization of Mg in the GaN crystals by a first-principles calculation. The optimization revealed that a compressive stress field was formed in the crystals when the lattice constant of the GaN crystals was fixed because Mg had a larger atom radius than Ga.

The more specific explanations are made below. The reference sign “d1” in FIG. 4 indicates a center-to-center distance between the Ga atoms and the N atoms in a c-axis direction after the structure optimization. The reference sign “d2” indicates a center-to-center distance between the Mg atoms and the N atoms in the c-axis direction after the structure optimization. The center-to-center distance d1 between Ga and N is 1.974 Å, and the center-to-center distance d2 between Mg and N is 2.057 Å. The distance d2 is greater than the distance d1 by 4.2%. The center-to-center distance is greater between the Mg atoms and the N atoms than between the Ga atoms and the N atoms, since the Mg atoms have a greater radius than the Ga atoms. An internal pressure of the GaN crystals including Mg shown in FIG. 4 obtained in accordance with the first-principles calculation by the inventors of the present disclosure was 0.406 GPa. The calculation revealed that the compressive stress field was formed inside the crystals because the pressure inside the crystals was the plus value.

### (Reduction of Compressive Stress Field)

The inventors of the present disclosure expected that the compressive stress field could be reduced to a level with no inclusion of Mg (no-defect crystals) or to a level including Mg of 3e18 cm⁻³, which would be estimated to be a solid solubility limit of Mg under the present conditions, by substitution of atoms other than Mg for a Ga site inside the crystals in which the compressive stress field was formed. The inventors of the present disclosure expected that the solid solubility limit caused by strain would be decreased even in the GaN crystals including Mg at a high concentration so as to introduce a larger amount of Mg into the Ga site if the compressive stress field could be reduced.

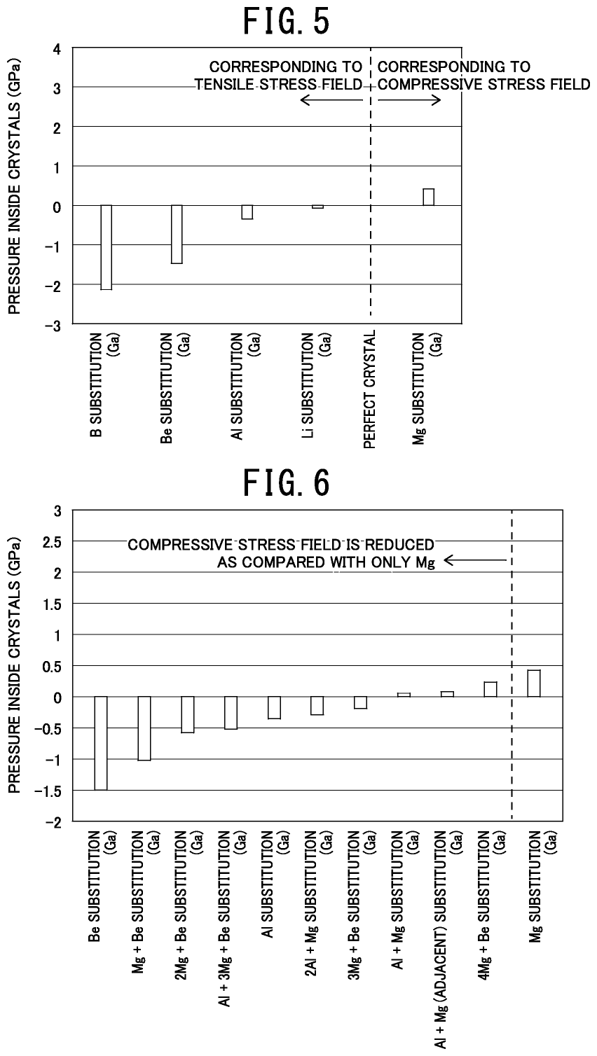

In view of the expectations describe above, the inventors of the present disclosure made a calculation similar to the case of Mg for some elements used as a dopant for the GaN crystals, and plotted the respective internal pressures of the GaN crystals to the graph as shown in FIG. 5. FIG. 5 shows the calculation results obtained by the first-principles calculation regarding the respective internal pressures in the GaN crystals in a case in which each of boron (B), aluminum (Al), lithium (Li) and beryllium (Be) is substituted for the Ga site in the GaN crystals. FIG. 5 shows the respective pressures (GPa) inside the crystals when the GaN lattice constant is fixed. FIG. 5 also shows the internal pressure in a case of substituting Mg for the Ga site for making a comparison.

The calculation revealed that, as shown in FIG. 5, a tensile stress field was formed in the GaN crystals when the GaN crystals were doped with B, Al, Li, or Be. It thus revealed that the addition of B, Al, Li, or Be to the GaN crystals together with Mg could offset the compressive stress field formed by Mg by the tensile stress field formed by B, Al, Li, or Be. The elements B and Al are each a group-13 element, and the elements Li and Be are each an acceptor element. These elements do not serve as an n-type dopant, and thus do not impede the p-type conduction of Mg at a high concentration, namely, the formation of the p⁺-type layer, regardless of whether these elements are doped together with Mg.

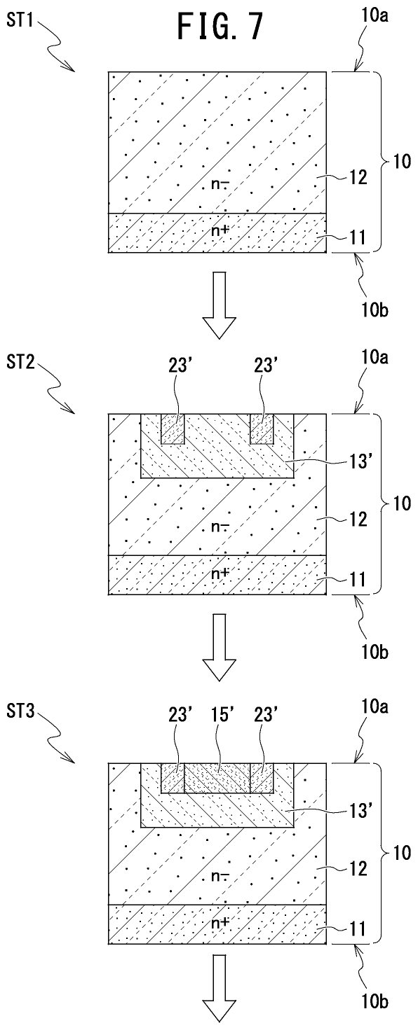

FIG. 6 is a graph showing calculation results obtained by the first-principles calculation regarding the respective internal pressures in the GaN crystals in a case in which either Al or Be and Mg are substituted for the Ga site in the GaN crystals. FIG. 6 shows the respective pressures (GPa) inside the crystals when the GaN lattice constant is fixed. FIG. 6 also shows the internal pressure in the case of substituting only Mg for the Ga site for making a comparison.

The item “Al+Mg substitution (Ga)” in the horizontal axis in FIG. 6 indicates a case in which the elements Al and Mg are substituted for the Ga site at an atom-number ratio of 1:1, and the respective elements Al and Mg after the substitution are separated from each other. The item “Al+Mg (adjacent) substitution (Ga)” indicates a case in which the elements Al and Mg are substituted for the Ga site at an atom-number ratio of 1:1, and the respective elements Al and Mg after the substitution are adjacent to each other. The item “Al+3 Mg+Be substitution (Ga)” indicates a case in which the elements Al, Mg, and Be are substituted for the Ga site at an atom-number ratio of 1:3:1, and the respective elements Al, Mg, and Be after the substitution are separated from each other. The common definitions are also applied to the other items.

It revealed that, as shown in FIG. 6, the introduction of at least either Al or Be in addition to Mg could greatly reduce the internal pressure so as to approximate to zero (the no-defect crystals), as compared with the case of the introduction of only Mg. The first-principles calculation shown in FIG. 6 revealed that the introduction of Al together with Mg at the atom-number ratio of 1:1 could lead the compressive stress field derived from Mg to approximate to zero GPa regardless of whether Mg and Al were adjacent to or separated from each other.

The first-principles calculation shown in FIG. 6 leads to the result in which the compressive stress field slightly remains when Al is supplied together with Mg at the ratio of 1:1. The calculation results, however, also revealed that the increase of Al supplied together with Mg to the ratio of 2:1 could completely eliminate the compressive stress field, and the tensile stress field caused by Al was predominantly formed instead. The results of the first-principles calculation made by the inventors of the present disclosure also revealed that the internal pressure was higher as the Mg concentration in the GaN crystals was higher, and the internal pressure was lower as the Mg concentration was lower. It further revealed that the introduction of Al could reduce the internal pressure at any Mg concentrations within the range of 3×10¹⁸ cm⁻³ or greater and 1×10²¹ cm⁻³ or less, for example.

The inventors of the present disclosure also calculated the stress field caused by Mg in wurtzite nitride crystals including the group-13 element other than Ga as cations by the first-principles calculation. The results revealed that the Mg substitution could cause a larger compressive stress field in the AlN crystals, which are a kind of wurtzite nitride crystals in which a cation-nitrogen distance is short. It is thus expected that the stress relaxation obtained by the configuration according to the present disclosure (the substitution by at least either B or Be in the case of the AlN crystals) is effective not only in the GaN crystals but also in the AlN crystals. The stress relaxation obtained by the configuration according to the present disclosure is also expected to be effective in any other mixed crystal systems when the compressive stress field is caused by the Mg substitution.

### (Manufacturing Method)

A method of manufacturing the GaN semiconductor device 100 illustrated in FIG. 1 to FIG. 3 is described below. The present embodiment is illustrated below with four ways of manufacturing the device. The GaN semiconductor device 100 can be manufactured by any of Manufacturing Method Examples 1 to 4 described below.

### (1) Manufacturing Method Example 1

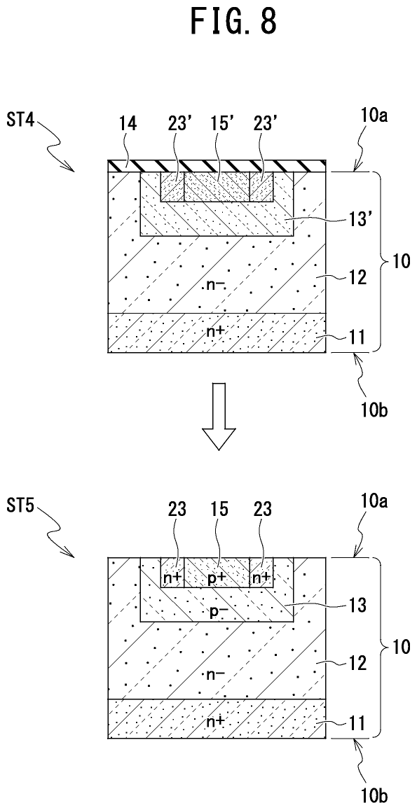

FIG. 7 and FIG. 8 are each a cross-sectional view illustrating a sequential procedure of Manufacturing Method Example 1 of the method of manufacturing the GaN semiconductor device 100 according to Embodiment 1 of the present disclosure. FIG. 7 and FIG. 8 each illustrate the sequential procedure of the manufacturing method regarding one of the vertical MOSFETs 1 repeatedly arranged in the X-axis direction. The GaN semiconductor device 100 is manufactured by use of several kinds of apparatuses, such as a film-forming apparatus, an exposing apparatus, an etching apparatus, an ion implantation apparatus, and an annealing apparatus. These apparatuses are collectively referred to below as a manufacturing apparatus.

As illustrated in step ST1 in FIG. 7, the manufacturing apparatus epitaxially grows the n⁻-type GaN layer 12 on one of the surfaces of the n⁺-type GaN single-crystal substrate 11. Next, as illustrated in step ST2 in FIG. 7, the manufacturing apparatus implants impurity ions of Mg as an acceptor element into a provisional region (referred to below as a “well-formed region”) 13′ in the GaN substrate 10 in which the p⁻-type well region 13 (refer to FIG. 3) is to be formed. This ion implantation is also referred to as a Mg (p) ion implantation. For example, the manufacturing apparatus forms a mask (not illustrated) over the front surface 10a of the GaN substrate 10. The mask is a SiO₂ film or a photoresist film that can be selectively removed from the GaN substrate 10. The mask is deposited to cover the front surface 10a other than the region over the well-formed region 13′ so as to expose the upper side of the well-formed region 13′. The manufacturing apparatus implants the impurity ions of Mg to the front surface 10a side of the GaN substrate 10 covered with the mask. The ion implantation of Mg in this case is made such that the Mg concentration in the well-formed region 13′ is set to 1×10¹⁸ cm⁻³. The manufacturing apparatus then removes the mask from the GaN substrate 10 after the ion implantation.

Next, the manufacturing apparatus implants impurity ions of Si as a donor element into a provisional region (referred to below as a “source-formed region”) 23′ in the GaN substrate 10 in which the n⁺-type source region 23 (refer to FIG. 3) is to be formed. This ion implantation is also referred to as a Si (n⁺) ion implantation. For example, the manufacturing apparatus forms a mask (not illustrated) over the front surface 10a of the GaN substrate 10. The mask is deposited to cover the front surface 10a other than the region over the source-formed region 23′ so as to expose the upper side of the source-formed region 23′. The manufacturing apparatus implants the impurity ions of Si to the front surface 10a side of the GaN substrate 10 covered with the mask. The ion implantation of Si in this case is made such that the Si concentration in the source-formed region 23′ is set to 1×10¹⁹ cm⁻³, for example. The manufacturing apparatus then removes the mask from the GaN substrate 10 after the ion implantation.

Next, as illustrated in step ST3 in FIG. 7, the manufacturing apparatus implants impurity ions of Al, which is an example of “at least either the group-13 element or the acceptor element” according to the present disclosure, into a provisional region (referred to below as a “contact-formed region”) 15′ in the GaN substrate 10 in which the p⁺-type contact region 15 (refer to FIG. 3) is to be formed. This ion implantation is also referred to as an Al ion implantation. For example, the manufacturing apparatus forms a mask (not illustrated) over the front surface 10a of the GaN substrate 10. The mask is deposited to cover the front surface 10a other than the region over the contact-formed region 15′ so as to expose the upper side of the contact-formed region 15′. The manufacturing apparatus implants the impurity ions of Al to the front surface 10a side of the GaN substrate 10 covered with the mask. The ion implantation of Al in this case is made such that the Al concentration in the contact-formed region 15′ is set in a range of 3×10¹⁷ cm⁻³ or greater and 5×10²¹ cm⁻³ or less (for example, set to 1.5×10¹⁹ cm⁻³).

Next, as illustrated in step ST4 in FIG. 8, the manufacturing apparatus implants impurity ions of Mg into the contact-formed region 15′ in the GaN substrate 10. This ion implantation is also referred to as a Mg (p⁺) ion implantation. For example, the manufacturing apparatus implants the impurity ions of Mg to the front surface 10a side of the GaN substrate 10 by use of the same mask as used in the Al ion implantation. The ion implantation of Mg in this case is made such that the Mg concentration in the contact-formed region 15′ is set in a range of 3×10¹⁸ cm⁻³ or greater and 1×10²¹ cm⁻³ or less (for example, set to 1×10¹⁹ cm⁻³).

Next, the manufacturing apparatus implants impurity ions of nitrogen (N) into the contact-formed region 15′ in the GaN substrate 10. This ion implantation is also referred to as an N ion implantation. For example, the manufacturing apparatus implants the impurity ions of N to the front surface 10a side of the GaN substrate 10 by use of the same mask as used in the Al ion implantation and in the p⁺ ion implantation. The ion implantation of N in this case is made such that the N concentration in the contact-formed region 15′ is set to 1×10¹⁹ cm⁻³, for example. The manufacturing apparatus then removes the mask from the GaN substrate 10 after the ion implantation. The N ion implantation described above is made in order to avoid a cause of nitrogen vacancies during annealing described below. The manufacturing method according to Embodiment 1 of the present disclosure, however, may omit the N ion implantation. The p⁺-type contact region 15 (refer to FIG. 3) can be formed regardless of whether the N ion implantation is made.

The process from step ST1 in FIG. 7 to step ST4 in FIG. 8 described above includes the Mg (p⁻) ion implantation, the Si (n⁺) ion implantation, the Al ion implantation, the Mg (p⁺) ion implantation, and the N ion implantation sequentially executed in this order. The manufacturing method according to Embodiment 1 of the present disclosure, however, is not limited to the order of the ion implantation steps described above. The Mg (p⁻) ion implantation, the Si (n⁺) ion implantation, the Al ion implantation, the Mg (p⁺) ion implantation, and the N ion implantation may be executed in any order. The GaN semiconductor device 100 illustrated in FIG. 1 to FIG. 3 can be manufactured regardless of the order of the ion implantation steps.

Next, the manufacturing apparatus forms a passivation film 14 on the front surface 10a of the GaN substrate 10. The passivation film 14 is an aluminum nitride (AlN) film, for example. The contact-formed region 15′ and the like in the GaN substrate 10 are thus covered with the passivation film 14. The manufacturing method according to Embodiment 1 of the present disclosure does not necessarily include the step of forming the passivation film 14.

Next, the manufacturing apparatus subjects the GaN substrate 10 to the annealing with a maximum temperature in a range of 1300° C. or higher and 2000° C. or lower. This annealing is rapid thermal annealing, for example. The annealing may be executed in a high-pressure N₂ atmosphere, such as 500 MPa, for example. The execution of the annealing activates the impurity ions of Mg and Si implanted to the GaN substrate 10. As illustrated in step ST5 in FIG. 8, the p⁻-type well region 13, the n⁺-type source region 23, and the p⁺-type contact region 15 are thus formed in the GaN substrate 10. The execution of the annealing can recover defects in the GaN substrate 10 to some extent caused through the respective ion implantation steps. After the annealing, the manufacturing apparatus removes the passivation film 14 from the front surface 10a of the GaN substrate 10.

Next, the manufacturing apparatus forms the gate insulating film 21 (refer to FIG. 3) on the front surface 10a of the GaN substrate 10. Next, the manufacturing apparatus forms the gate electrode 22 (refer to FIG. 3) and the source electrode 25 (refer to FIG. 3). Next, the manufacturing apparatus forms the drain electrode 26 (refer to FIG. 3) on the rear surface 10b side of the GaN substrate 10. The GaN semiconductor device 100 including the vertical MOSFET 1 is thus completed through the procedure as described above.

### (2) Manufacturing Method Example 2

Manufacturing Method Example 1 has been illustrated above with the case of doping the GaN layer 12 with Al by the ion implantation. The means of doping with Al in the manufacturing method according to Embodiment 1 of the present disclosure is not limited to the ion implantation. The doping with Al may be made such that an Al-doped layer 31 is epitaxially grown on the GaN layer 12, as described below.

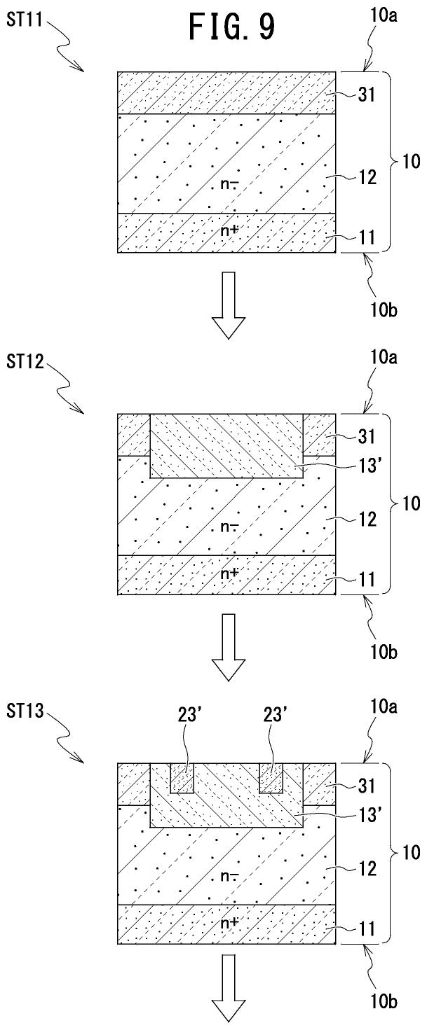

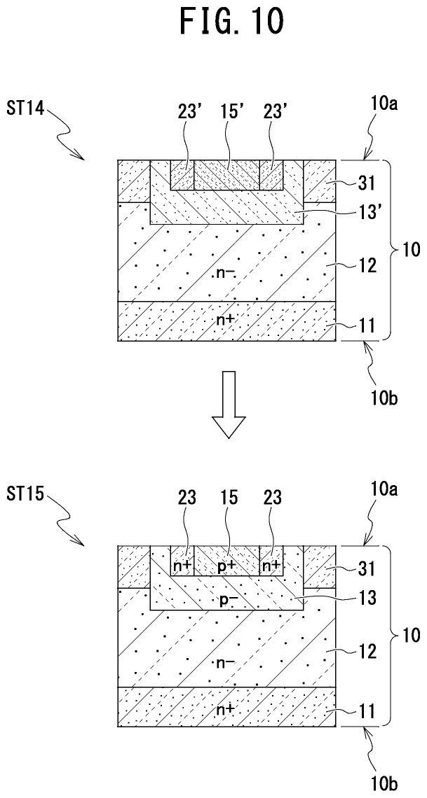

FIG. 9 and FIG. 10 are each a cross-sectional view illustrating a sequential procedure of Manufacturing Method Example 2 of the method of manufacturing the GaN semiconductor device 100 according to Embodiment 1 of the present disclosure. As illustrated in step ST11 in FIG. 9, the manufacturing apparatus epitaxially grows the n⁻-type GaN layer 12 and the Al-doped layer 31 sequentially on one of the surfaces of the n⁺-type GaN single-crystal substrate 11. The Al-doped layer 31 is a single-crystal GaN layer including Al. The Al-doped layer 31 includes Al at a concentration of 1.5×10¹⁹ cm⁻³, for example. The Al-doped layer 31 has a thickness in a range of 20 nanometers or greater and 100 nanometers or smaller. The GaN layer 12 and the Al-doped layer 31 are an example of a “nitride crystal layer” according to the present disclosure.

Next, as illustrated in step ST12 in FIG. 9, the manufacturing apparatus implants impurity ions of Mg as an acceptor element into the well-formed region 13′ of the GaN substrate 10 including the Al-doped layer 31. This Mg (p⁻) ion implantation is made by use of a mask (not illustrated) in the same manner as Manufacturing Method Example 1. The ion implantation of Mg in this case is made such that the Mg concentration in the well-formed region 13′ is set to 1×10¹⁸ cm⁻³, as in the case of Manufacturing Method Example 1.

Next, as illustrated in step ST13 in FIG. 9, the manufacturing apparatus implants impurity ions of Si as a donor element into the source-formed region 23′ of the GaN substrate 10 including the Al-doped layer 31. This Si (n⁺) ion implantation is made by use of a mask (not illustrated) in the same manner as Manufacturing Method Example 1. The ion implantation of Si in this case is made such that the Si concentration in the source-formed region 23′ is set to 1×10¹⁹ cm⁻³, as in the case of Manufacturing Method Example 1.

Next, as illustrated in step ST14 in FIG. 10, the manufacturing apparatus implants impurity ions of Mg into the contact-formed region 15′ of the GaN substrate 10 including the Al-doped layer 31. This Mg (p⁺) ion implantation is made by use of a mask (not illustrated) in the same manner as Manufacturing Method Example 1. The ion implantation of Mg in this case is made such that the Mg concentration in the contact-formed region 15′ is set to 1×10¹⁹ cm⁻³, as in the case of Manufacturing Method Example 1. An implantation energy during the Mg (p⁺) ion implantation is set such that a peak depth of Mg implanted from the front surface 10a of the GaN substrate 10 is shallower than the thickness of the Al-doped layer 31. Namely, the implantation energy during the Mg (p⁺) ion implantation is set so as to lead the peak depth of the Mg implantation is located in the Al-doped layer 31.

This step causes a part of the Al-doped layer 31 to be the contact-formed region 15′. The contact-formed region 15′ includes Al at a concentration of 1.5×10¹⁹ cm⁻³ and Mg at a concentration of 1×10¹⁹ cm⁻³. The manufacturing apparatus may execute the additional steps, such as the step of implanting the impurity ions of N into the GaN substrate 10 and the step of forming the passivation film, before the execution of the annealing for activating Mg and the like, as in the case of Manufacturing Method Example 1. The steps of the implantation of N and the formation of the passivation film are optional. Further, the Mg (p⁻) ion implantation, the Si (n⁺) ion implantation, the Mg (p⁺) ion implantation, and the N ion implantation may be executed in any order, as in the case of Manufacturing Method Example 1.

Next, the manufacturing apparatus subjects the GaN substrate 10 to the annealing with a maximum temperature in a range of 1300° C. or higher and 2000° C. or lower. This annealing is rapid thermal annealing, for example. The annealing may be executed in a high-pressure N₂ atmosphere, such as 500 MPa, for example. The execution of the annealing activates Mg and Si implanted to the GaN substrate 10. As illustrated in step ST15 in FIG. 10, the p⁻-type well region 13, the n⁺-type source region 23, and the p⁺-type contact region 15 are thus formed in the GaN substrate 10.

The execution of the annealing described above can also recover defects in the GaN substrate 10 to some extent caused through the respective ion implantation steps. Further, Manufacturing Method Example 2 forms the contact-formed region 15′ inside the Al-doped layer 31 and thus does not need to execute the implantation of Al, so as to eliminate a problem of crystal defects caused by the Al ion implantation. Manufacturing Method Example 2 thus could prevent or reduce the crystal defects derived from the execution of the ion implantations with much higher reliability than Manufacturing Method Example 1.

The Al-doped layer 31 has the thickness in the range of 20 nanometers or greater and 100 nanometers or smaller, as described above. This thickness is thinner than a thickness of typical AlGaN. The Al-doped layer 31 includes Al with the concentration in a range of 3×10¹⁷ cm⁻³ or greater and 5×10²¹ cm⁻³ or smaller, and is 1.5×10¹⁹ cm⁻³, for example. Forming the Al-doped layer 31 with the small thickness and the Al concentration in the range as described above can minimize a change in the lattice constant of GaN when arranged on the GaN layer 12. This can further sufficiently suppress a decrease in control performance for conductivity due to spontaneous polarization. The other subsequent steps are the same as those in Manufacturing Method Example 1. The manufacturing apparatus forms the gate insulating film 21, the gate electrode 22, the source electrode 25, and the drain electrode 26 illustrated in FIG. 3. The GaN semiconductor device 100 including the vertical MOSFET 1 is thus completed through the procedure as described above.

### (3) Manufacturing Method Example 3

The means of doping with Al is not limited to either the ion implantation or the epitaxial growth. The doping with Al may be made by thermal diffusion from a film including Al toward the GaN layer 12. This film may be a Mg—Al compound so as to include not only Al but also Mg. The p⁺-type contact region 15 may be formed by the thermal diffusion of Al and Mg from the Mg—Al compound toward the GaN layer 12.

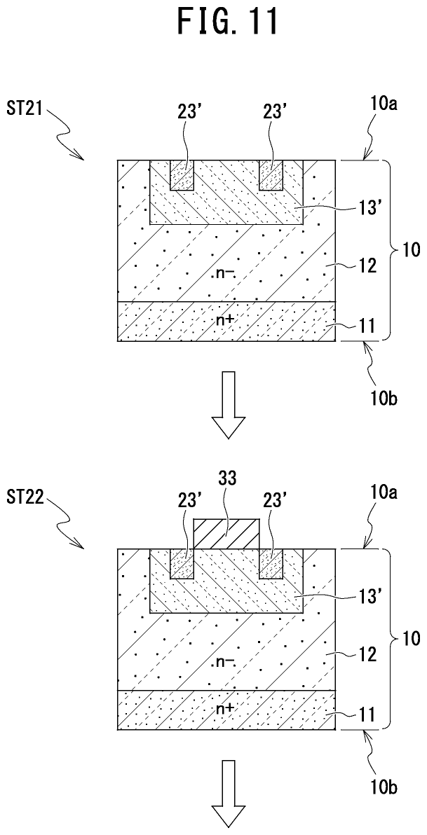

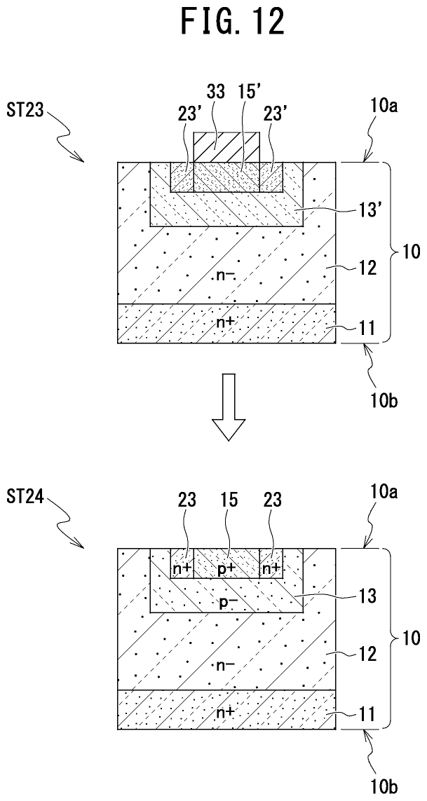

FIG. 11 and FIG. 12 are each a cross-sectional view illustrating a sequential procedure of Manufacturing Method Example 3 of the method of manufacturing the GaN semiconductor device 100 according to Embodiment 1 of the present disclosure. Manufacturing Method Example 3 illustrated in step ST21 in FIG. 11 includes the same process as steps ST1 and ST2 of forming the well-formed region 13′ and forming the source-formed region 23′ illustrated in FIG. 7.

After forming the well-formed region 13′ and the source-formed region 23′, the manufacturing apparatus forms a Mg—Al compound 33 including Mg and Al, which is an example of a “first film” and is also an example of a “second film” according to the present disclosure, on the front surface 10a of the GaN substrate 10, as illustrated in step ST22 in FIG. 11. The Mg—Al compound 33 is Al₃Mg₂, for example. The formation of Al₃Mg₂ is made by sputtering, electron-beam vapor deposition, or thermal vapor deposition, for example.

Before the formation of the Mg—Al compound 33, impurity ions of nitrogen (N) may be preliminarily implanted to a region in the GaN layer 12 in which the Mg—Al compound 33 is to be deposited, which corresponds to the contact-formed region 15′. The impurity ions of N may be implanted to the region in which the Mg—Al compound 33 is to be deposited so as to have a concentration of N set to 2×10¹⁹ cm⁻³, for example.

Next, as illustrated in step ST23 in FIG. 12, the manufacturing apparatus subjects the entire substrate including the Mg—Al compound 33 and the GaN layer 12 to annealing, which is an example of “first annealing” and also an example of “second annealing” according to the present disclosure, so as to thermally diffuse Mg and Al from the Mg—Al compound 33 toward the GaN layer 12. The annealing for the thermal diffusion of Mg and Al is executed under the conditions of a maximum temperature of 800° C. and a treatment time at the maximum temperature of five minutes in an N₂ atmosphere, for example. This annealing leads Mg and Al to be introduced into the contact-formed region 15′. After the introduction of Mg and Al into the contact-formed region 15′, the manufacturing apparatus removes the Mg—Al compound 33 from the front surface 10a of the GaN substrate 10.

Next, the manufacturing apparatus subjects the GaN substrate 10 to annealing with a maximum temperature in a range of 1300° C. or higher and 2000° C. or lower. This annealing is rapid thermal annealing, for example. The annealing may be executed in a high-pressure N₂ atmosphere, such as 500 MPa, for example. The execution of the annealing activates Mg and Si introduced to the GaN substrate 10. As illustrated in step ST24 in FIG. 12, the p⁻-type well region 13, the n⁺-type source region 23, and the p⁺-type contact region 15 are thus formed in the GaN substrate 10.

The execution of the annealing described above can also recover defects in the GaN substrate 10 to some extent caused through the respective ion implantation steps. Manufacturing Method Example 3 executes the introduction of Al and Mg into the contact-formed region 15′ not by the ion implantation but by the thermal diffusion. Manufacturing Method Example 3 thus could prevent or reduce the crystal defects derived from the execution of the ion implantations with much higher reliability than Manufacturing Method Example 1. The other subsequent steps are the same as those in Manufacturing Method Example 1. The manufacturing apparatus forms the gate insulating film 21, the gate electrode 22, the source electrode 25, and the drain electrode 26 illustrated in FIG. 3. The GaN semiconductor device 100 including the vertical MOSFET 1 is thus completed through the procedure as described above.

### (4) Manufacturing Method Example 4

The manufacturing method according to Embodiment 1 of the present disclosure may combine Manufacturing Method Example 2 and Manufacturing Method Example 3. For example, the introduction of Al into the GaN layer 12 may be executed by the epitaxial growth of the Al-doped layer 31. The introduction of Mg into the GaN layer 12 may be executed such that a film serving as a supply source of Mg, such as a Mg film, is formed on the Al-doped layer 31 so that Mg is thermally diffused from the Mg film toward the Al-doped layer 31.

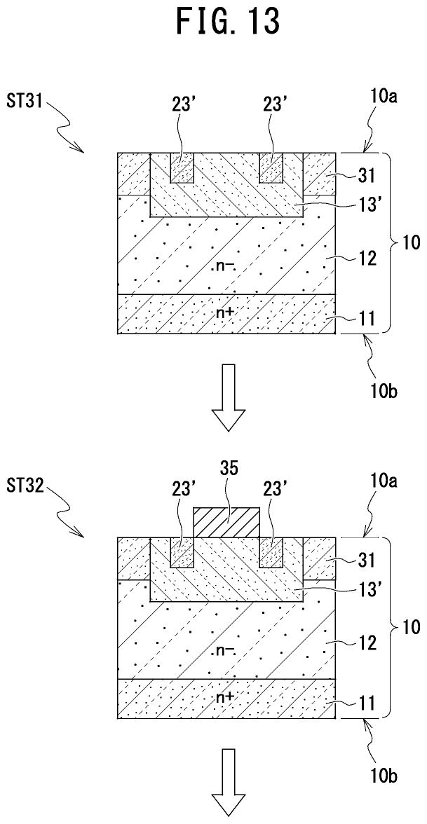

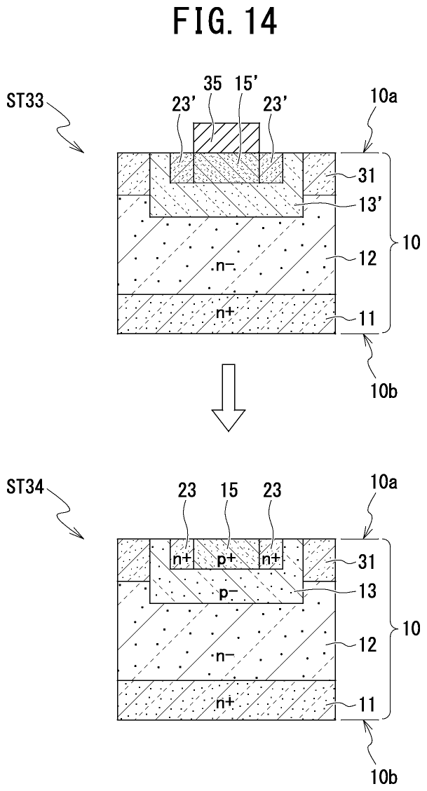

FIG. 13 and FIG. 14 are each a cross-sectional view illustrating a sequential procedure of Manufacturing Method Example 4 of the method of manufacturing the GaN semiconductor device 100 according to Embodiment 1 of the present disclosure. Manufacturing Method Example 4 illustrated in step ST31 in FIG. 13 includes the same process as the steps ST11, ST12, and ST13 of forming the Al-doped layer 31, forming the well-formed region 13′, and forming the source-formed region 23′ illustrated in FIG. 9.

After forming the well-formed region 13′ and the source-formed region 23′, the manufacturing apparatus forms a Mg film 35, which is an example of the “first film” according to the present disclosure, on the front surface 10a of the GaN substrate 10, as illustrated in step ST32 in FIG. 13. The formation of the Mg film 35 is made by sputtering, electron-beam vapor deposition, or thermal vapor deposition, for example. Before the formation of the Mg film 35, impurity ions of nitrogen (N) may be preliminarily implanted to a region in the GaN layer 12 in which the Mg film 35 is to be deposited, which corresponds to the contact-formed region 15′. The impurity ions of N may be implanted to the region in which the Mg film 35 is to be deposited so as to have a concentration of N set to 2×10¹⁹ cm⁻³, for example.

Next, as illustrated in step ST33 in FIG. 14, the manufacturing apparatus subjects the entire substrate including the Mg film 35 and the GaN layer 12 to annealing, which is an example of the “first annealing” according to the present disclosure, so as to thermally diffuse Mg from the Mg film 35 toward the GaN layer 12. The annealing for the thermal diffusion of Mg is executed under the conditions of a maximum temperature of 800° C. and a treatment time at the maximum temperature of five minutes in a N₂ atmosphere, for example. This annealing leads Mg to be introduced into the contact-formed region 15′. After the introduction of Mg into the contact-formed region 15′ including Al, the manufacturing apparatus removes the Mg film 35 from the front surface 10a of the GaN substrate 10.

Next, the manufacturing apparatus subjects the GaN substrate 10 to annealing with a maximum temperature in a range of 1300° C. or higher and 2000° C. or lower. This annealing is rapid thermal annealing, for example. The annealing may be executed in a high-pressure N₂ atmosphere, such as 500 MPa, for example. The execution of the annealing activates Mg and Si introduced to the GaN substrate 10. As illustrated in step ST34 in FIG. 14, the p⁻-type well region 13, the n⁺-type source region 23, and the p⁺-type contact region 15 are thus formed in the GaN substrate 10.

The execution of the annealing described above can also recover defects in the GaN substrate 10 to some extent caused through the respective ion implantation steps. Manufacturing Method Example 4 executes the introduction of Al and Mg into the contact-formed region 15′ not by the ion implantation but by the formation of the Al-doped layer 31 and by the thermal diffusion of Mg. Manufacturing Method Example 4 thus could prevent or reduce the crystal defects derived from the execution of the ion implantations with much higher reliability than Manufacturing Method Example 1. The other subsequent steps are the same as those in Manufacturing Method Example 1. The manufacturing apparatus forms the gate insulating film 21, the gate electrode 22, the source electrode 25, and the drain electrode 26 illustrated in FIG. 3. The GaN semiconductor device 100 including the vertical MOSFET 1 is thus completed through the procedure as described above.

### Effects of Embodiment 1

As described above, the GaN semiconductor device 100 according to Embodiment 1 of the present disclosure includes the n⁻-type GaN layer 12 and the p⁺-type contact region 15 provided in the GaN layer 12. The contact region 15 includes Mg at the concentration in the range of 3×10¹⁸ cm⁻³ or greater and 1×10²¹ cm⁻³ or less, and at least either the group-13 element or the acceptor element at the concentration in the range of 3×10¹⁷ cm⁻³ or greater and 5×10²¹ cm⁻³ or less.

The configuration described above can offset the compressive stress field caused by Mg in the p⁺-type contact region 15 by the compressive stress field caused by at least either the group-13 element or the acceptor element, which is Al, for example. This can reduce the compressive stress field formed around Mg, so as to improve the solid solubility limit of Mg. This configuration can also increase the amount of Mg entering the Ga site and avoid segregation of Mg, so as to provide the p⁺-type region (the p⁺-type contact region 15 in this example) with the high concentration. This embodiment thus can achieve a preferable ohmic contact between the p⁺-type contact region 15 and the source electrode 25.

### Modified Example of Embodiment 1

While Embodiment 1 of the present disclosure has illustrated the “p-type region” with the p⁺-type contact region 15 as described above, the “p-type region” according to the present disclosure is not limited to the p⁺-type contact region. The “p-type region” according to the present disclosure may be a p⁺-type withstand voltage layer, or may be both the p⁺-type contact layer and the p⁺-type withstand voltage layer, for example.

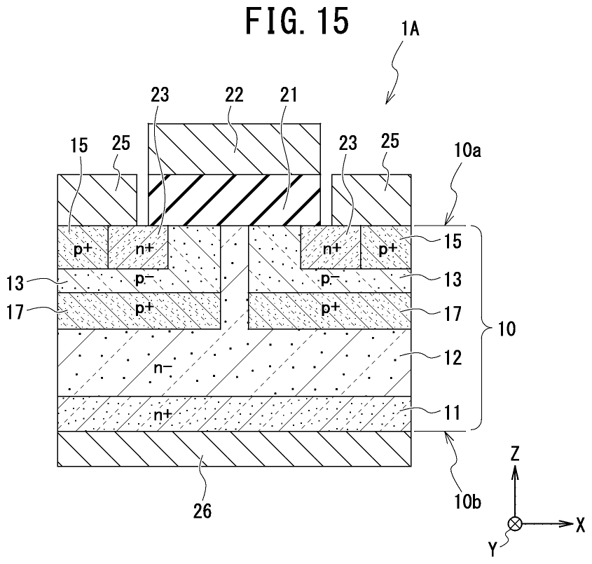

FIG. 15 is a cross-sectional view illustrating a configuration of a vertical MOSFET 1A according to a modified example of Embodiment 1 of the present disclosure. As illustrated in FIG. 15, the GaN substrate 10 of the vertical MOSFET 1A includes a p⁺-type buried layer 17 deposited between the p⁻-type well region 13 and the n⁻-type GaN layer 12 (the drift layer). In this modified example, the p⁺-type contact region 15 and the p⁺-type buried layer 17 are each the example of the “p-type region” according to the present disclosure.

The p⁺-type buried layer 17 is formed such that p-type impurity ions such as Mg are implanted to the front surface 10a side of the GaN substrate 10 and then subjected to annealing so as to be activated. The p⁺-type buried layer 17 includes the p-type impurities of Mg at a concentration in a range of 3×10¹⁸ cm⁻³ or greater and 1×10²¹ cm⁻³ or less. A peak concentration of M in the p⁺-type buried layer 17 in the depth direction is 5×10¹⁸ cm⁻³ or greater, preferably 8×10¹⁹ cm⁻³ or greater, and more preferably 1×10¹⁹ cm⁻³ or greater.

The p⁺-type buried layer 17 further includes at least either a group-13 element or an acceptor element at a concentration in a range of 3×10¹⁷ cm⁻³ or greater and 5×10²¹ cm⁻³ or less, and more preferably in a range of 2×10¹⁸ cm⁻³ or greater and 5×10²¹ cm⁻³ or less, in order to reduce the compressive stress field formed around Mg. The group-13 element is at least either B or Al, for example. The acceptor element is at least either Li or Be, for example. The p⁺-type buried layer 17 includes Al, for example, as the group-13 element at the concentration in the range of 3×10¹⁷ cm⁻³ or greater and 5×10²¹ cm⁻³ or less, and more preferably in the range of 2×10¹⁸ cm⁻³ or greater and 5×10²¹ cm⁻³ or less. The p⁺-type buried layer 17 has a thickness in a range of 0.1 micrometers or greater and 0.5 micrometers or smaller, for example.

The provision of the p⁺-type buried layer 17 between the p⁻-type well region 13 and the n⁻-type GaN layer 12 (the drift region) leads a depletion layer to expand between the p⁺-type buried layer 17 and the drift region, so as to improve breakdown voltage between the p⁺-type buried layer 17 and the drift region. For example, the p⁺-type buried layer 17 can enhance the breakdown voltage of the vertical MOSFET 1A when an input voltage toward the gate electrode 22 is at a low level, namely during a gate-off state, as compared with a case of not being provided with the p⁺-type buried layer 17. The GaN semiconductor device according to the modified example of Embodiment 1 includes a plurality of vertical MOSFETs 1A illustrated in FIG. 15. Each of the vertical MOSFETs 1A is a single unit of repeatedly-arranged structures. The GaN semiconductor device according to the modified example thus has the configuration including the plural single units aligned in one direction, which is the X-axis direction, for example.

As described above, the vertical MOSFET 1A according to the modified example of Embodiment 1 of the present disclosure includes the p⁺-type contact region 15 and the p⁺-type buried layer 17 provided in the n⁻-type GaN layer 12. The p⁺-type contact region 15 and the p⁺-type buried layer 17 each include Mg at the concentration in the range of 3×10¹⁸ cm⁻³ or greater and 1×10²¹ cm⁻³ or less, and at least either the group-13 element or the acceptor element (Al, for example) at the concentration in the range of 3×10¹⁷ cm⁻³ or greater and 5×10²¹ cm⁻³ or less.

The configuration described above can offset the compressive stress field caused by Mg in each of the p⁺-type contact region 15 and the p⁺-type buried layer 17 by the compressive stress field caused by Al. This can reduce the compressive stress field formed around Mg, so as to improve the solid solubility limit of Mg. This configuration can also increase the amount of Mg entering the Ga site and avoid segregation of Mg, so as to provide the p⁺-type region (the p⁺-type contact region 15 and the p⁺-type buried layer 17 in this example) with the high concentration. Further, the provision of the p⁺-type buried layer 17 between the p⁻-type well region 13 and the n⁻-type GaN layer 12 (the drift region) leads the depletion layer to expand between the p⁺-type buried layer 17 and the drift region, so as to improve the breakdown voltage during the gate-off state, for example.

### Embodiment 2

Embodiment 1 has been illustrated above with the case in which the vertical MOSFETs 1 and 1A each have the planar structure. The vertical MOSFET having the “p-type region” according to the present disclosure is not limited to the planar structure but may have a trench-gate structure.

### Configuration Example

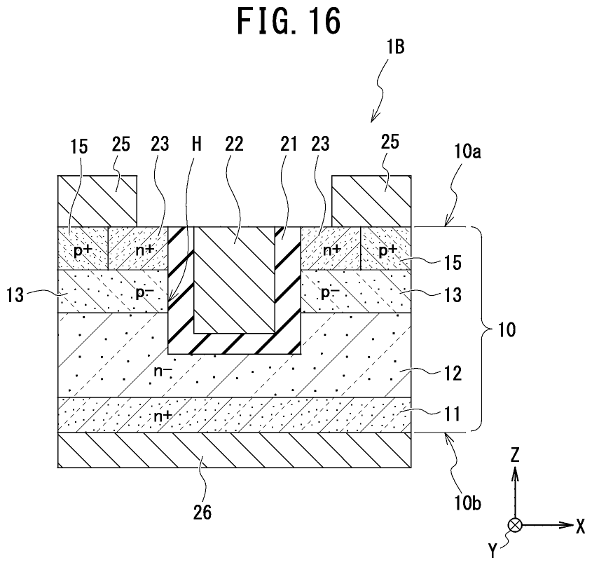

FIG. 16 is a cross-sectional view illustrating a configuration example of a vertical MOSFET 1B according to Embodiment 2 of the present disclosure. As illustrated in FIG. 16, the vertical MOSFET 1B according to Embodiment 2 has a trench-gate structure. In particular, the vertical MOSFET 1B has a trench H provided in the GaN substrate 10. The trench H is open toward the front surface 10a side of the GaN substrate 10. The trench H has a greater depth than the p⁻-type well region 13 so that the bottom of the trench H reaches the inside of the n⁻-type GaN layer 12.

The gate insulating film 21 and the gate electrode 22 are arranged inside the trench H. The side surfaces and the bottom surface of the trench H are covered with the gate insulating film 21. The gate electrode 22 is buried in the trench H with the gate insulating film 21 interposed. The vertical MOSFET 1B has a channel region that is a part of the p⁻-type well region 13 opposed to the gate electrode 22 via the gate insulating film 21 provided along the side surfaces on the inside of the trench H.

### Effects of Embodiment 2

The vertical MOSFET 1B also includes the p⁺-type contact region 15 including Mg at the concentration in the range of 3×10¹⁸ cm⁻³ or greater and 1×10²¹ cm⁻³ or less and at least either the group-13 element or the acceptor element (Al, for example) at the concentration in the range of 3×10¹⁷ cm⁻³ or greater and 5×10²¹ cm⁻³ or less.

The configuration described above can also reduce the compressive stress field formed around Mg in the p⁺-type contact region 15, so as to improve the solid solubility limit of Mg, as in the case of the vertical MOSFET 1 according to Embodiment 1. This configuration can further increase the amount of Mg entering the Ga site and avoid segregation of Mg, so as to provide the p⁺-type region (the p⁺-type contact region 15 in this example) with the high concentration. The configuration described above thus can achieve a preferable ohmic contact between the p⁺-type contact region 15 and the source electrode 25. Further, the configuration of the vertical MOSFET 1B can contribute to minimization of the size due to the trench-gate structure, so as to improve a channel density to ensure low-ON resistance.

### Modified Examples of Embodiment 2

### (1) Modified Example 1

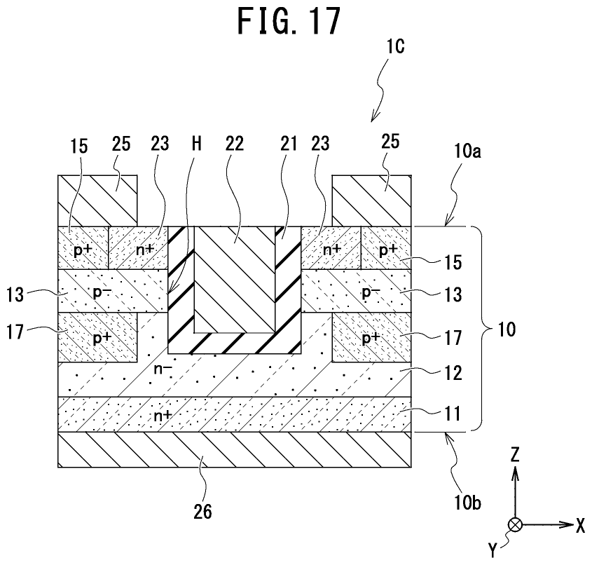

FIG. 17 is a cross-sectional view illustrating a configuration of a vertical MOSFET 1C according to Modified Example 1 of Embodiment 2 of the present disclosure. As illustrated in FIG. 17, the vertical MOSFET 1C according to Modified Example 1 of Embodiment 2 includes the p⁺-type buried layer 17 deposited between the p⁻-type well region 13 and the n⁻-type GaN layer 12 (the drift layer), as in the case of the vertical MOSFET 1A (refer to FIG. 15) according to the modified example of Embodiment 1. In Modified Example 1, the p⁺-type contact region 15 and the p⁺-type buried layer 17 are each the example of the “p-type region” according to the present disclosure.

The p⁺-type buried layer 17 illustrated in FIG. 17 has the same configuration as the p⁺-type buried layer 17 illustrated in FIG. 15. In particular, the p⁺-type buried layer 17 includes Mg as p-type impurities at a concentration in a range of 3×10¹⁸ cm⁻³ or greater and 1×10²¹ cm⁻³ or less. The p⁺-type buried layer 17 further includes at least either a group-13 element or an acceptor element (Al, for example) at a concentration in a range of 3×10¹⁷ cm⁻³ or greater and 5×10²¹ cm⁻³ or less, and more preferably in a range of 1×10¹⁸ cm⁻³ or greater and 2×10²¹ cm⁻³ or less, in order to reduce the compressive stress field formed around Mg.

The configuration described above can reduce the compressive stress field formed around Mg in each of the p⁺-type contact region 15 and the p⁺-type buried layer 17, so as to improve the solid solubility limit of Mg, as in the case of the modified example of Embodiment 1. This configuration can also increase the amount of Mg entering the Ga site and avoid segregation of Mg, so as to achieve the p⁺-type region (the p⁺-type contact region 15 and the p⁺-type buried layer 17 in this example) with the high concentration.

Further, the p⁺-type buried layer 17 having a higher p-type impurity concentration than the p⁻-type well region 13 is arranged between the p⁻-type well region 13 and the n⁻-type GaN layer 12 (the drift region). For example, the p⁺-type buried layer 17 is deposited separately from the channel region so as to reach a position deeper than the bottom of the trench H. This configuration leads a depletion layer to expand between the p⁺-type buried layer 17 and the drift region to relax an electric field concentration on the bottom of the trench H, so as to improve the breakdown voltage during the gate-off state, for example.

### (2) Modified Example 2

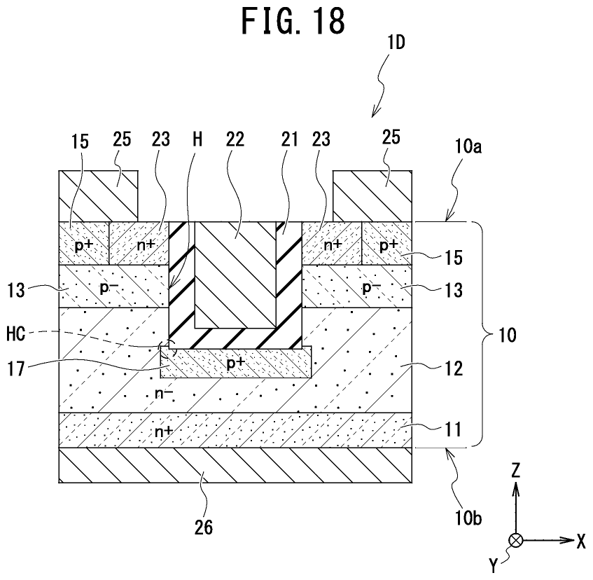

FIG. 18 is a cross-sectional view illustrating a configuration of a vertical MOSFET 1D according to Modified Example 2 of Embodiment 2 of the present disclosure. As illustrated in FIG. 18, the vertical MOSFET 1D according to Modified Example 2 of Embodiment 2 includes the p⁺-type buried layer 17 arranged at the bottom of the trench H. The p⁺-type buried layer 17 is provided to have a wider width than the bottom of the trench H in each of the X-axis direction and the Y-axis direction, for example. The p⁺-type buried layer 17 is deposited continuously from a part shallower than the bottom of the trench H (a position closer to the front surface 10a) to a part deeper than the bottom of the trench H (a position closer to the rear surface 10b). The bottom of the trench H including the corners HC is thus covered with the p⁺-type buried layer 17.

This configuration can also provide the p⁺-type region (the p⁺-type contact region 15 and the p⁺-type buried layer 17 in this example) with the high concentration, as in the case of Modified Example 1 of Embodiment 2 described above. While an electric field tends to be concentrated on the bottom of the trench H, particularly at the corners HC, close to the drain electrode 26, this configuration leads a depletion layer to expand from the p⁺-type buried layer 17 provided at the bottom of the trench H toward the drift region side, so as to relax the electric field concentration on the bottom or the corners HC of the trench H. This can suppress damage to the gate insulating film 21 caused by the electric field concentration on the bottom or the corners HC of the trench H.

While Modified Example 2 in FIG. 18 is illustrated above with the case in which the p⁺-type buried layer 17 has the greater width than the bottom of the trench H, the p⁺-type buried layer 17 does not need to have a wider width than the bottom of the trench H. The p⁺-type buried layer 17 may have the same width as the bottom of the trench H, for example.

In addition, Modified Example 2 is illustrated above with the case in which the p⁺-type buried layer 17 is arranged from the position shallower than the bottom of the trench H to the position deeper than the bottom of the trench H, but is not limited to this case. The p⁺-type buried layer 17 in this example only needs to be in contact with the bottom of the trench H. For example, the p⁺-type buried layer 17 may be arranged from the same position as the bottom of the trench H to a position deeper than the bottom of the trench H.

### Embodiment 3

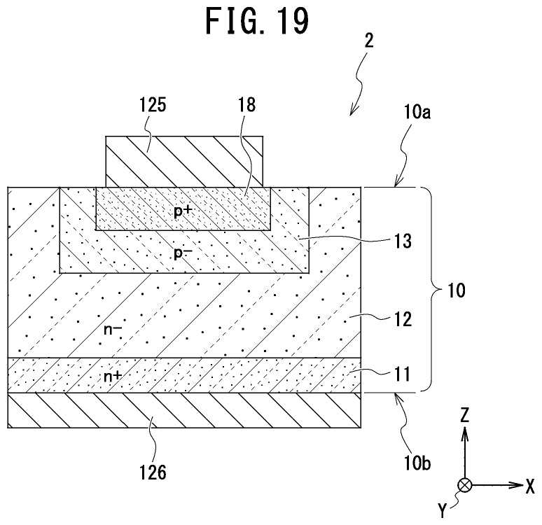

The present disclosure is not necessarily applied to the case in which the “p-type region” is the field-effect transistor. The “p-type region” according to the present disclosure may be a p-n diode, for example. FIG. 19 is a cross-sectional view illustrating a configuration example of a p-n diode 2 according to Embodiment 3 of the present disclosure. As illustrated in FIG. 19, the p-n diode 2 includes the GaN substrate 10 including the n⁺-type GaN single-crystal substrate 11 and the n⁻-type GaN layer 12, the p⁻-type well region 13 provided in the GaN substrate 10 so as to be in contact with the n⁻-type GaN layer 12, and a p⁺-type layer 18 provided in the GaN substrate 10 so as to be in contact with the well region 13. The p⁺-type layer 18 is deposited inside the p⁻-type well region 13 so as to have a surface at the same level as the front surface 10a of the GaN substrate 10.

The p-n diode 2 includes the p⁺-type layer 18 and the p⁻-type well region 13 each serving as an anode region, and the n⁺-type GaN single-crystal substrate 11 and the n⁻-type GaN layer 12 each serving as a cathode region. Embodiment 3 is illustrated with the case in which the p⁺-type layer 18 is the “p-type region” according to the present disclosure. The p-n diode 2 further includes an anode electrode 125 provided on the front surface 10a side of the GaN substrate 10 so as to be in contact with the p⁺-type layer 18, and a cathode electrode 126 provided on the rear surface 10b side of the GaN substrate 10 so as to be in contact with the n⁺-type GaN single-crystal substrate 11. The anode electrode 125 and the cathode electrode 126 each include Al or an Al—Si alloy, for example. A barrier metal layer may be provided between the GaN substrate 10 and each of the anode electrode 125 and the cathode electrode 126. The barrier metal layer may include T1.

The p⁺-type layer 18 has the same configuration as the p⁺-type contact region 15 as described in each of Embodiments 1 and 2, for example. In particular, the p⁺-type layer 18 includes Mg as p-type impurities at a concentration in a range of 3×10¹⁸ cm⁻³ or greater and 1×10²¹ cm⁻³ or less, and more preferably in a range of 1×10¹⁹ cm⁻³ or greater and 2×10²⁰ cm⁻³ or less. The p⁺-type layer 18 further includes at least either a group-13 element or an acceptor element (Al, for example) at a concentration in a range of 3×10¹⁷ cm⁻³ or greater and 5×10²¹ cm⁻³ or less, and more preferably in a range of 5×10¹⁸ cm⁻³ or greater and 4×10²⁰ cm⁻³ or less, in order to reduce the compressive stress field formed around Mg.

The configuration described above can offset the compressive stress field caused by Mg in the p⁺-type layer 18 serving as the anode region of the p-n diode 2 by the compressive stress field caused by Al. This can reduce the compressive stress field formed around Mg, so as to improve the solid solubility limit of Mg. This configuration can also increase the amount of Mg entering the Ga site and avoid segregation of Mg, so as to provide the p⁺-type region (the p⁺-type layer 18 in this example) with the high concentration. This embodiment thus can achieve a preferable ohmic contact between the p⁺-type layer 18 and the anode electrode 125.

### Other Embodiments

While the present disclosure has been described above by reference to Embodiments 1 to 3 and the respective modified examples, it should be understood that the present disclosure is not intended to limit the descriptions and the drawings composing part of this disclosure. Various alternative embodiments and modified examples will be apparent to those skilled in the art according to this disclosure. For example, while FIG. 1 illustrates the case in which the p⁺-type contact region 15 has a stripe shape extending in the Y-axis direction in the planar view as viewed in the Z-axis direction, the shape of the p⁺-type contact region 15 in the planar view as viewed in the Z-axis direction is not limited to the stripe shape. The p⁺-type contact region 15 may have a polygonal shape such as a rectangular shape, a hexagonal shape, and an octagonal shape, or may have a circular shape in the planar view as viewed in the Z-axis direction.

It should be understood that the present disclosure can include various embodiments not disclosed herein, and can include at least various omissions, replacements, or modifications of the components without departing from the teaching of Embodiments 1 to 3 and the respective modified examples described above. It should also be understood that the effects described herein are illustrated merely as some examples that are not limited to the above descriptions, and the present disclosure may have any other effects not disclosed herein. Therefore, the technical scope of the present disclosure is defined only by the subject matter according to the claims reasonably derived from the foregoing descriptions.

The present disclosure can also have the following configurations.
(1) A nitride semiconductor device including:
   a nitride crystal layer; and
   a p-type region provided in the nitride crystal layer,
   wherein the p-type region includes
      Mg at a concentration in a range of 3×10¹⁸ cm⁻³ or greater and 1×10²¹ cm⁻³ or less, and
      at least either a group-13 element or an acceptor element at a concentration in a range of 3×10¹⁷ cm⁻³ or greater and 5×10²¹ cm⁻³ or less.
(2) The nitride semiconductor device of the above (1), wherein the group-13 element is at least either B or Al.
(3) The nitride semiconductor device of the above (1) or (2), wherein the acceptor element is at least either Li or Be.
(4) The nitride semiconductor device of any one of the above (1) to (3), further including a nitride crystal substrate, wherein
   the nitride crystal layer is provided on one surface of the nitride crystal substrate, and
   a lattice constant of the p-type region in each of a first direction parallel to the one surface and a second direction parallel to the one surface and perpendicular to the first direction is equal to a lattice constant of the nitride crystal substrate in each of the first direction and the second direction.
(5) The nitride semiconductor device of any one of the above (1) to (4), further including:
   a well region of p-type provided in the nitride crystal layer; and
   a field-effect transistor provided in the nitride crystal layer and having a configuration of being provided with a channel in the well region,
   wherein the p-type region includes the acceptor element with the concentration greater than that of the well region, and is electrically connected to the well region.
(6) The nitride semiconductor device of any one of the above (1) to (4), further including a diode provided in the nitride crystal layer,
   wherein the p-type region is an anode region of the diode.
(7) A method of manufacturing a nitride semiconductor device, including:
   introducing Mg to a nitride crystal layer at a concentration in a range of 3×10¹⁸ cm⁻³ or greater and 1×10²¹ cm⁻³ or less;
   introducing at least either a group-13 element or an acceptor element to a region of the nitride crystal layer to which Mg is introduced at a concentration in a range of 3×10¹⁷ cm⁻³ or greater and 5×10²¹ cm⁻³ or less; and
   forming a p-type region in the nitride crystal layer by subjecting, to annealing, the nitride crystal layer to which Mg and at least either the group-13 element or the acceptor element are introduced so as to activate Mg.
(8) The method of manufacturing the nitride semiconductor device of the above (7), further including implanting impurity ions of N to a region of the nitride crystal layer to which Mg is introduced,
   wherein the forming the p-type region subjects, to the annealing, the nitride crystal layer to which the impurity ions of N are implanted.
(9) The method of manufacturing the nitride semiconductor device of the above (8), further including forming a passivation film on the nitride crystal layer to which Mg is introduced and the impurity ions of N are implanted,
   wherein the forming the p-type region subjects the nitride crystal layer provided with the passivation film to the annealing.
(10) The method of manufacturing the nitride semiconductor device of any one of the above (7) to (9), wherein the introducing Mg to the nitride crystal layer is made by ion implantation of Mg to the nitride crystal layer.
(11) The method of manufacturing the nitride semiconductor device of any one of the above (7) to (9), wherein the introducing Mg to the nitride crystal layer is made such that:
   a first film including Mg is formed on the nitride crystal layer; and
   the nitride crystal layer provided with the first film is subjected to a first annealing so as to thermally diffuse Mg from the first film to the nitride crystal layer.
(12) The method of manufacturing the nitride semiconductor device of any one of the above (7) to (11), wherein the introducing at least either the group-13 element or the acceptor element to the nitride crystal layer is made by ion implantation of at least either the group-13 element or the acceptor element to the nitride crystal layer.
(13) The method of manufacturing the nitride semiconductor device of any one of the above (7) to (11), wherein the introducing at least either the group-13 element or the acceptor element is made such that:
   a second film including at least either the group-13 element or the acceptor element is formed on the nitride crystal layer; and
   the nitride crystal layer provided with the second film is subjected to a second annealing so as to thermally diffuse at least either the group-13 element or the acceptor element from the second film to the nitride crystal layer.

What is claimed is:

1. A nitride semiconductor device comprising:
a nitride crystal layer; and
a p-type region provided in the nitride crystal layer,
wherein the p-type region includes
Mg at a concentration in a range of 3×10¹⁸ cm⁻³ or greater and 1×10²¹ cm⁻³ or less, and
at least either a group-13 element or an acceptor element at a concentration in a range of 3×10¹⁷ cm⁻³ or greater and 5×10²¹ cm⁻³ or less.

2. The nitride semiconductor device of claim 1, wherein the group-13 element is at least either B or Al.

3. The nitride semiconductor device of claim 1, wherein the acceptor element is at least either Li or Be.

4. The nitride semiconductor device of claim 1, further comprising a nitride crystal substrate, wherein
the nitride crystal layer is provided on one surface of the nitride crystal substrate, and
a lattice constant of the p-type region in each of a first direction parallel to the one surface and a second direction parallel to the one surface and perpendicular to the first direction is equal to a lattice constant of the nitride crystal substrate in each of the first direction and the second direction.

5. The nitride semiconductor device of claim 1, further comprising:
a well region of p-type provided in the nitride crystal layer; and
a field-effect transistor provided in the nitride crystal layer and having a configuration of being provided with a channel in the well region,
wherein the p-type region includes the acceptor element with the concentration greater than that of the well region, and is electrically connected to the well region.

6. The nitride semiconductor device of claim 1, further comprising a diode provided in the nitride crystal layer,
wherein the p-type region is an anode region of the diode.

7. A method of manufacturing a nitride semiconductor device, comprising:
introducing Mg to a nitride crystal layer at a concentration in a range of 3×10¹⁸ cm⁻³ or greater and 1×10²¹ cm⁻³ or less;
introducing at least either a group-13 element or an acceptor element to a region of the nitride crystal layer to which Mg is introduced at a concentration in a range of 3×10¹⁷ cm⁻³ or greater and 5×10²¹ cm⁻³ or less; and
forming a p-type region in the nitride crystal layer by subjecting, to annealing, the nitride crystal layer to which Mg and at least either the group-13 element or the acceptor element are introduced so as to activate Mg.

8. The method of manufacturing the nitride semiconductor device of claim 7, further comprising implanting impurity ions of N to a region of the nitride crystal layer to which Mg is introduced,
wherein the forming the p-type region subjects, to the annealing, the nitride crystal layer to which the impurity ions of N are implanted.

9. The method of manufacturing the nitride semiconductor device of claim 8, further comprising forming a passivation film on the nitride crystal layer to which Mg is introduced and the impurity ions of N are implanted,
wherein the forming the p-type region subjects the nitride crystal layer provided with the passivation film to the annealing.

10. The method of manufacturing the nitride semiconductor device of claim 7, wherein the introducing Mg to the nitride crystal layer is made by ion implantation of Mg to the nitride crystal layer.

11. The method of manufacturing the nitride semiconductor device of claim 7, wherein the introducing Mg to the nitride crystal layer is made such that:
a first film including Mg is formed on the nitride crystal layer; and
the nitride crystal layer provided with the first film is subjected to a first annealing so as to thermally diffuse Mg from the first film to the nitride crystal layer.

12. The method of manufacturing the nitride semiconductor device of claim 7, wherein the introducing at least either the group-13 element or the acceptor element to the nitride crystal layer is made by ion implantation of at least either the group-13 element or the acceptor element to the nitride crystal layer.

13. The method of manufacturing the nitride semiconductor device of claim 7, wherein the introducing at least either the group-13 element or the acceptor element is made such that:
a second film including at least either the group-13 element or the acceptor element is formed on the nitride crystal layer; and
the nitride crystal layer provided with the second film is subjected to a second annealing so as to thermally diffuse at least either the group-13 element or the acceptor element from the second film to the nitride crystal layer.
